(19) United States
(12) Patent Application Publication
(10) Pub. No.: US 2012/0103259 A1
(43) Pub. Date: May 3, 2012

(54) THIN FILM DEPOSITING APPARATUS

(75) Inventors: Woo-Seok CHEONG, Daejeon (KR); Yeong-Shin Kim, Daejeon (KR)

(73) Assignees: Yeong-Shin & KIM, Daejeon (KR); ELECTRONICS AND TELECOMMUNICATIONS RESEARCH INSTITUTE, Daejeon (KR)

(21) Appl. No.: 13/182,955

(22) Filed: Jul. 14, 2011

(30) Foreign Application Priority Data
Oct. 27, 2010 (KR) 10-2010-0105303

(51) Int. Cl. C23C 16/50

(52) U.S. Cl. 118/723 R

(57) ABSTRACT

Provided is a thin film depositing apparatus. The thin film depositing apparatus includes: a process chamber including at least one sputter gun inducing a first plasma on a film or a flat plate; a loading unit provided at one side of the process chamber and including first and second loading chambers loading the film or the flat plate into the process chamber; and an unloading unit provided at the other side of the process chamber facing the loading unit and including first and second loading chambers including first and second unloading chambers unloading the film or the flat plate from the process chamber, wherein the first loading chamber is connected to the first unloading chamber or the second loading chamber is connected to the second unloading chamber at both sides of the process chamber.

### CROSS-REFERENCE TO RELATED APPLICATIONS

This U.S. non-provisional patent application claims priority under 35 U.S.C. §119 of Korean Patent Application No. 10-2010-0105303, filed on Oct. 27, 2010, the entire contents of which are hereby incorporated by reference.

### BACKGROUND OF THE INVENTION

The present invention disclosed herein relates to a thin film depositing apparatus, and more particularly, to a thin film depositing apparatus depositing a thin film on a film or a flat plate.

A high-performance thin film becomes greatly utilized because of development of electronic communication technology. Moreover, Research and Development (R&D) for mass production of the high-performance thin film is actively in progress. For example, the high performance thin layer may be massively deposited on a film through a roll-to-roll way. The high performance thin film sometimes needs to be formed on a flat plate at the request of the consumer. Since a typical thin film depositing apparatus is manufactured to meet only one process of a film or a flat plate, mass production may be deteriorated.

### SUMMARY OF THE INVENTION

The present invention provides a thin film depositing apparatus for both a film and a flat plate during thin film deposition.

The present invention also provides a thin film depositing apparatus for increasing or maximizing productivity.

Embodiments of the present invention provide thin film depositing apparatuses including: a process chamber including at least one sputter gun inducing a first plasma on a film or a flat plate; a loading unit provided at one side of the process chamber and including first and second loading chambers loading the film or the flat plate into the process chamber; and an unloading unit provided at the other side of the process chamber facing the loading unit and including first and second unloading chambers unloading the film or the flat plate from the process chamber, wherein the first loading chamber is connected to the first unloading chamber or the second loading chamber is connected to the second unloading chamber at both sides of the process chamber.

In some embodiments, the process chamber may include a plurality of rollers transferring and supporting the flat plate or the film.

In other embodiments, the rollers may include a plurality of transfer rollers are disposed adjacent to the both sidewalls in the process chamber and transferring the flat plate or the film and a supporting roller supporting the flat plate or the film between the plurality of transfer rollers.

In still other embodiments, each of the plurality of transfer rollers may include a plurality of parallel rollers and a vertical roller below between the plurality parallel rollers.

In even other embodiments, the process chamber may further include a protection cap surrounding the supporting roller, being adjacent to the sputter gun.

In yet other embodiments, the protection cap may have a V-shape.

In further embodiments, the process chamber may further include a plurality of shutters disposed between the sputter gun and the transfer rollers.

In still further embodiments, ***.

In even further embodiments, the process chamber may include a preliminary chamber cleansing the flat plate and the film and a deposition chamber connected to the preliminary chamber and depositing a thin film on the flat plate and the film.

In yet further embodiments, the deposition chamber may further include one of the flat plate and the film and a plurality of inductive coupled plasma tubes disposed at both sides between the sputter guns and inducing a more expanded second plasma than the first plasma.

In yet further embodiments, the first loading chamber may further include an unwinding roller unwinding the film and the first unloading chamber further includes a winding roller winding the film.

In yet further embodiments, each of the first loading chamber and the first unloading chamber may further include a plurality of film direction changing roller changing a transfer direction of the film and heaters thermally processing the film between the plurality of film direction changing rollers.

In yet further embodiments, each of the second loading chamber and the second unloading chamber may further include a cassette elevator loading the flat plate and moving it up and down.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1A and 1B are sectional views of a thin film depositing apparatus according to an embodiment of the present invention;

FIGS. 2A and 2B are sectional views illustrating the respective insides of the film loading/unloading chambers and the flat plate loading/unloading chambers of FIGS. 1A and 1B;

FIGS. 3A and 3B are sectional views illustrating the insides of the preliminary chamber FIGS. 1A and 1B; and

FIGS. 4A and 4B are sectional views illustrating the insides of the deposition chamber of FIGS. 1A and 1B.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

While specific terms were used, they were not used to limit the meaning or the scope of the present invention described in Claims, but merely used to explain the present invention. The meaning of “include,” “comprise,” “including,” or “comprising,” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto.

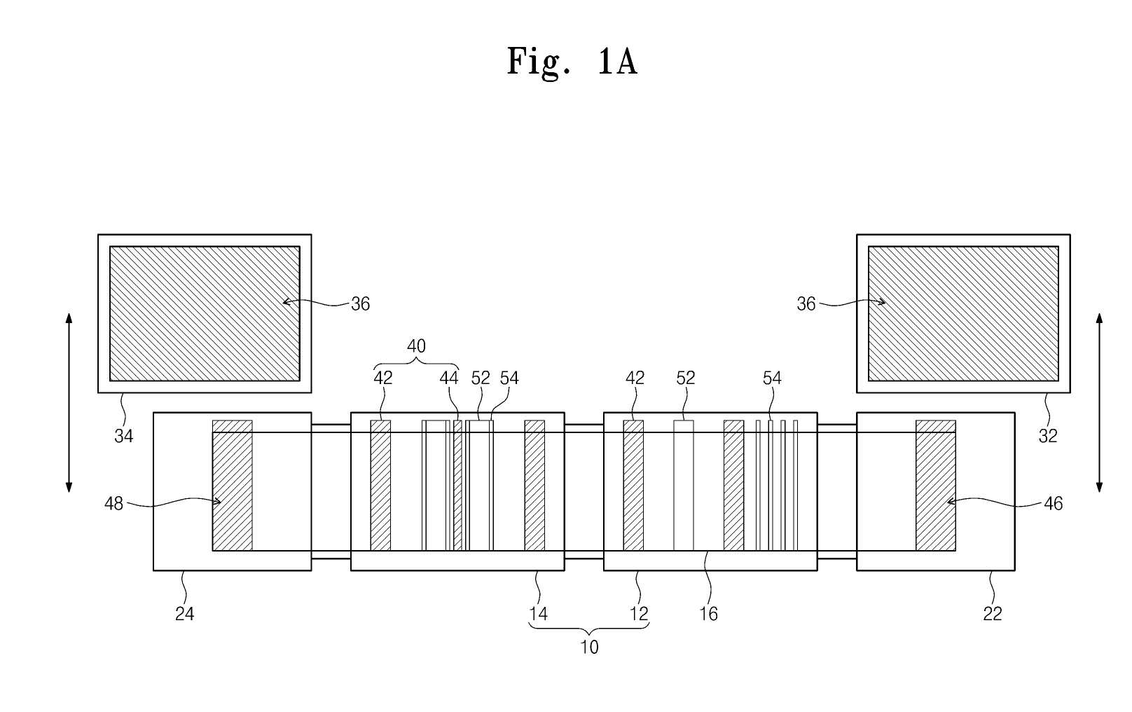

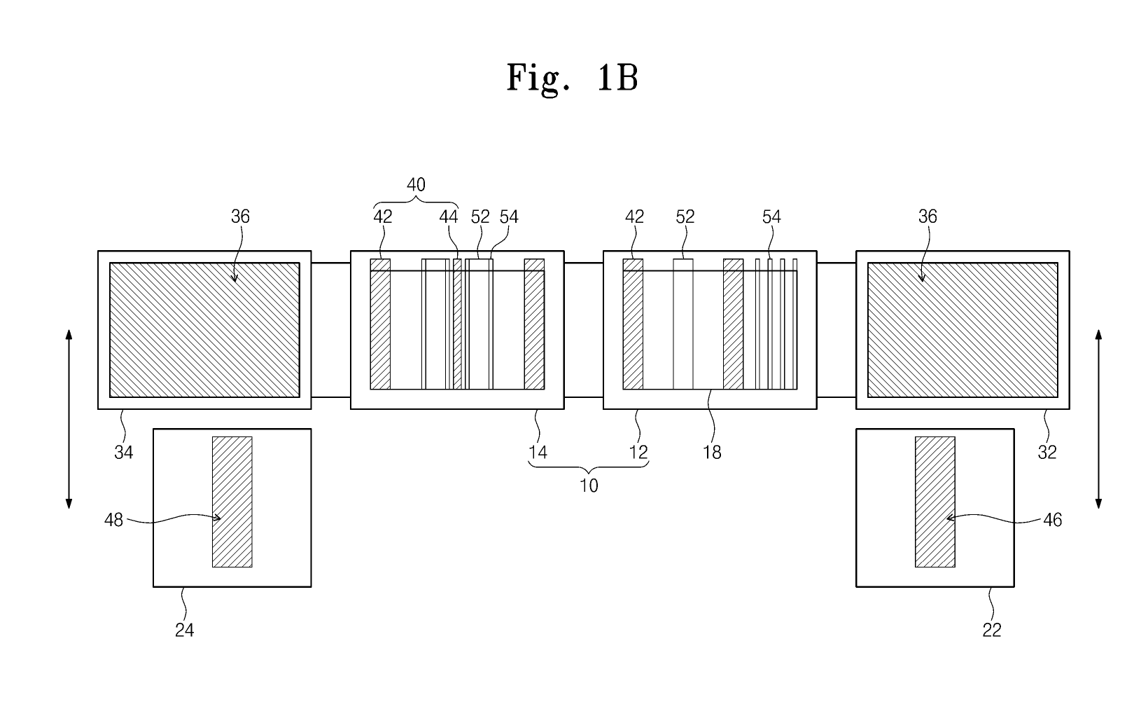

FIGS. 1A and 1B are sectional views of a thin film depositing apparatus according to an embodiment of the present invention.

Referring to FIGS. 1A and 1B, the thin film depositing device may include a film loading chamber 22 and a film unloading chamber 24, which are selectively connected at the facing both sides of process chambers 10 according to a thin film depositing process of one of a film 16 and flat plates 18, a flat plate loading chamber 32, and a flat plate unloading chamber 34. The process chambers 10 may include a preliminary chamber 12 and a deposition chamber 14. The process chamber 10, the film loading chamber 22, and the film unloading chamber 24 may be laniary disposed during a thin film depositing process of the film 16. Additionally, the process chambers 10, the flat plate loading chamber 23, and the flat plate unloading chamber 34 may be linearly disposed during a thin film depositing process of the flat plates 18. Each of the film loading chamber 22, the film unloading chamber 24, the flat plate loading chamber 32, and the flat plate unloading chamber 34 may move vertical to the preliminary chamber 12 and the deposition chamber 14.

Accordingly, since the thin film depositing apparatus may be used for both the film 16 and the flat plates 18 during a thin film depositing process, productivity may be increased or maximized. The film loading chamber 22 and the film unloading chamber 24 may be a first loading chamber and a first unloading chamber, respectively. The flat plate loading chamber 32 and the flat plate unloading chamber 34 may be a second loading chamber and a second unloading chamber, respectively. Additionally, the film loading chamber 22 and the float plate loading chamber 32 may be a loading unit. The film unloading chamber 24 and the flat plate unloading chamber 34 may be an unloading unit.

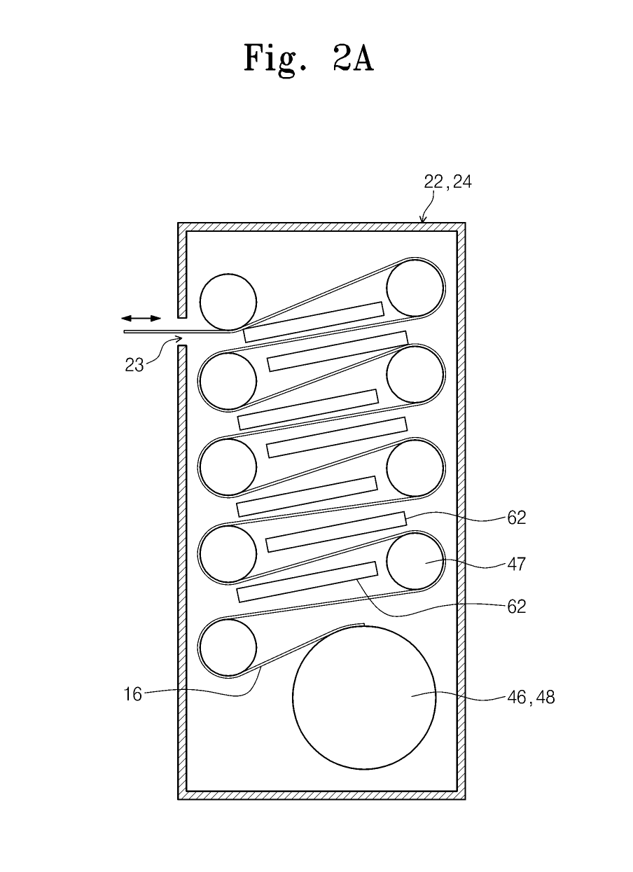

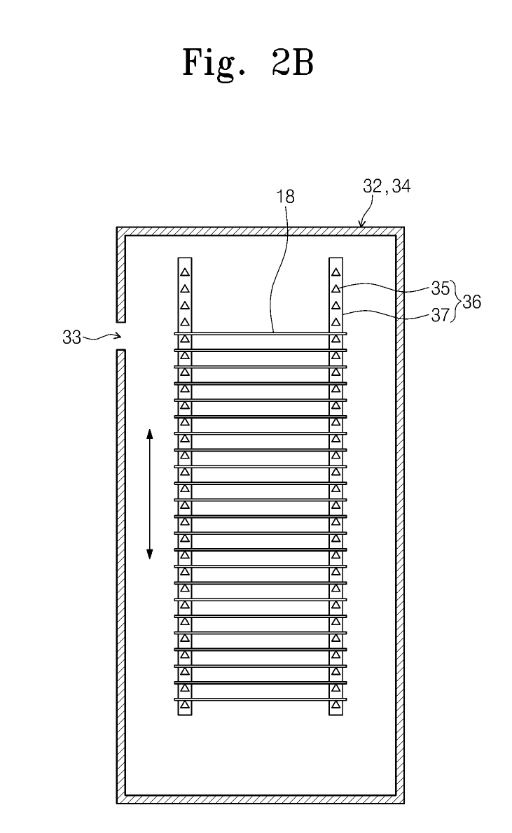

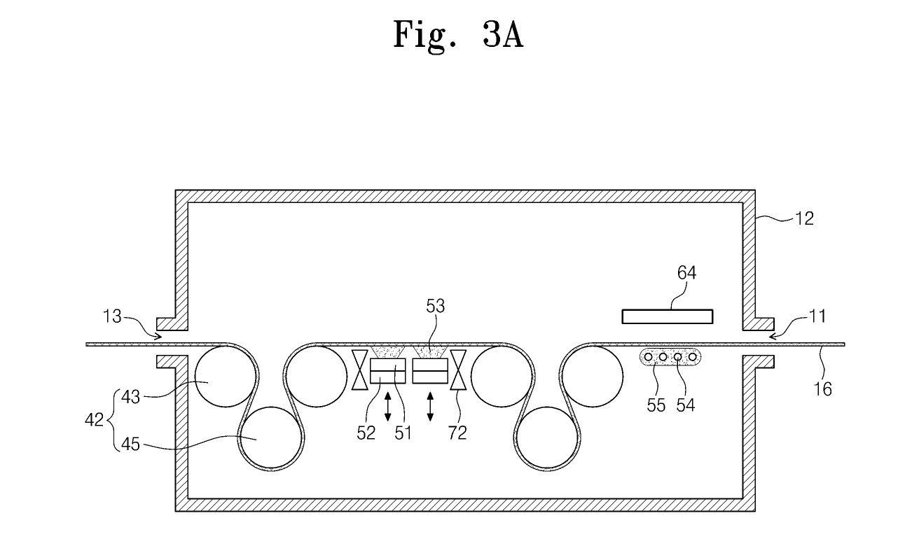

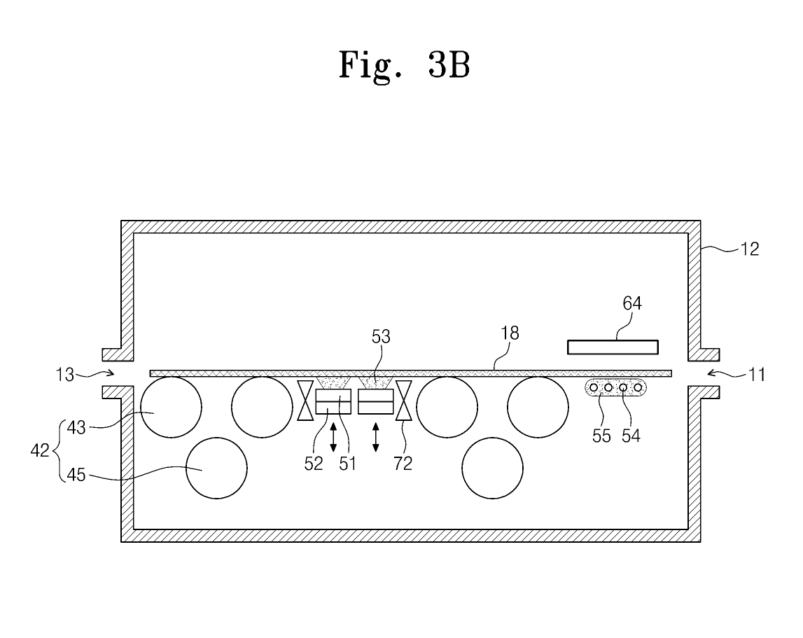

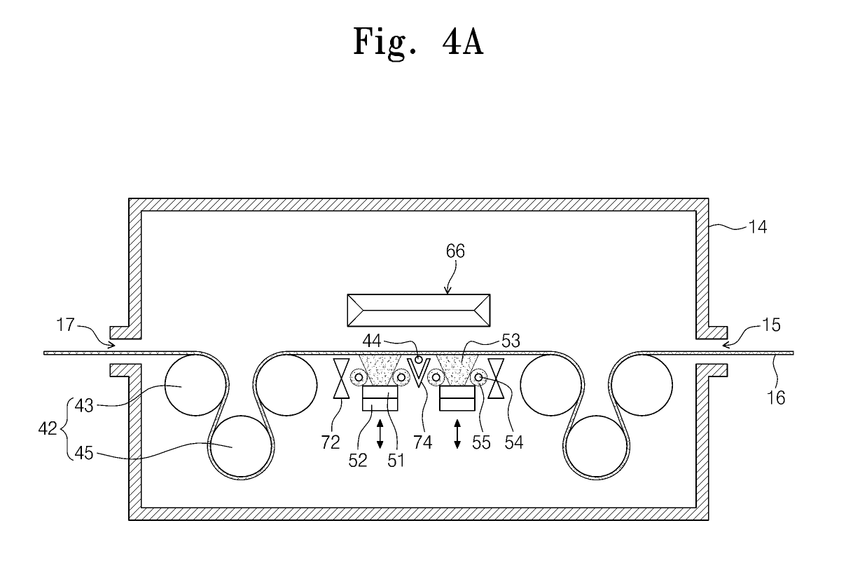

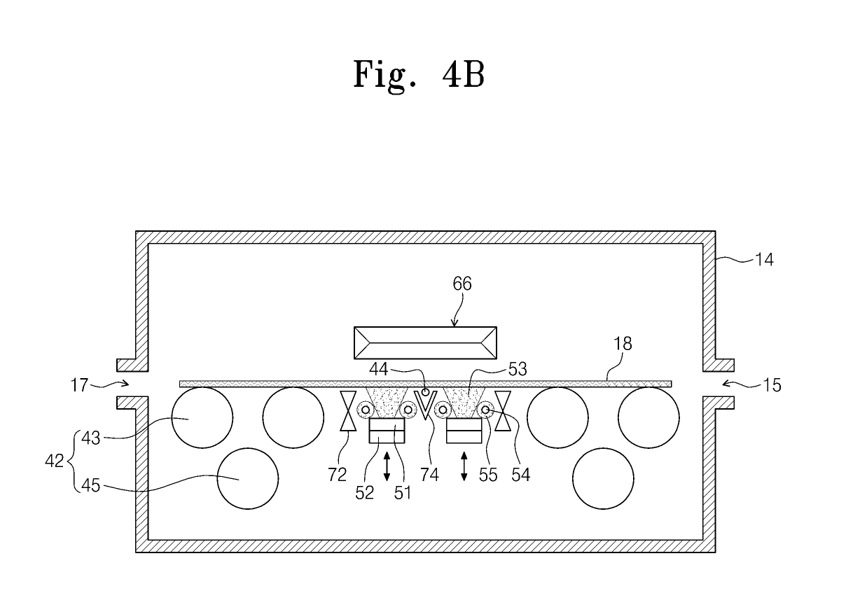

FIGS. 2A and 2B are sectional views illustrating the respective insides of the film loading/unloading chambers and the flat plate loading/unloading chambers of FIGS. 1A and 1B. FIGS. 3A and 3B are sectional views illustrating the insides of the preliminary chamber FIGS. 1A and 1B. FIGS. 4A and 4B are sectional views illustrating the insides of the deposition chamber of FIGS. 1A and 1B.

Referring to FIGS. 1A through 3B, the film loading chamber 22 may include a unwinding roller 46 unwinding a film 16, and film unloading chamber 24 may include a winding roller 48 winding the film 16. The unwinding roller 46 may unwind the film 16 at a predetermined tension. The winding roller 48 may wind the film 16. Accordingly, the film loading chamber 22 and the film unloading chamber 24 may disposed in a pair at the both sides of the process chambers 10. A first entrance 23 of the film loading chamber 22 may be connected to a first inlet 11 of the preliminary chamber 12. A first entrance 23 of the film unloading chamber 24 may be connected to a second exit 17 of the deposition chamber 14. The film loading chamber 22 and the film unloading chamber 24 may maintain a predetermined vacuum pressure through a pumping system (not shown).

The film 16 may change its transfer direction in the film loading chamber 22 and the film unloading chamber 24 using a plurality of direction changing rollers 47. The plurality of direction changing rollers 47 may be staggered from the bottoms to the tops of the loading/unloading chambers 22 and 24. For example, the plurality of direction changing rollers 47 may be symmetrically disposed on the sidewalls at the both side of each of the film loading chamber 22 and the film unloading chamber 24 facing the first entrance. The film 16 may be heated by first heaters 62 between the direction changing rollers 47. In the film loading chamber 22, heat from the first heaters 62 may increase flexibility of the film 16. At this point, an impurity in the film 16 may be outgasing. The first heaters 62 may perform an annealing process on a thin film on the film 16 in the film unloading chamber 24. For example, the first heaters 62 may heat the film 16 up to about 200° C.

Referring to FIGS. 1B and 2B, the flat plate loading chamber 32 and the flat plate unloading chamber 34 may include cassette elevators 36 loading the flat plates 18 and moving them up and down. The cassette elevators 36 may include slots 35 supporting the flat plates 18, frames 37 fixing the slots 35 at a predetermined interval, and a lifter (not shown) raising and lowering the frames 37. The cassette elevators 36 may load flat plates 18 of about 20 to about 100. The flat plates 18 may sequentially transfer from the flat plate loading chamber 32 to the process chamber 10 using a feeding system (not shown) such as a robot arm. Additionally, the flat plates 18 may transfer from the process chamber 10 to the flat plate unloading chamber 34 using the feeding system (not shown). Accordingly, the flat plates 18 may linearly transferred in the flat plate loading chamber 32, the flat plate unloading chamber 34, and the process chamber 10. The flat plate loading chamber 32 and the flat plate unloading chamber 34 may be disposed in a pair at the both sides of the process chamber 10. The second entrance 33 of the flat plate loading chamber 32 may be connected to the first inlet 11 of the preliminary chamber 12. The second entrance 23 of the flat plate unloading chamber 34 may be connected to the second exit 17 of the deposition chamber 14.

Referring to FIG. 1A through 3B, the preliminary chamber 12 may be disposed between the film loading chamber 22 or the flat plate loading chamber 32 and the deposition chamber 14. The preliminary chamber 12 may be always connected to the deposition chamber 14. The first exit 13 of the preliminary chamber 12 may be connected to the second inlet 15 of the deposition chamber 14. On the contrary, the preliminary chamber 12 may be selectively connected to the film loading chamber 22 or the flat loading chamber 32. The inlet 11 of the preliminary chamber 12 may be selectively connected to one of the first entrance 23 and the second entrance 33.

The preliminary chamber 12 may perform a preliminary process for cleansing or heating the film 16 or the flat plates 18 transferred from the first entrance 11 to the first exit 13. Additionally, the preliminary process may include a process for forming a buffer layer (not shown) on the film 16 and the flat plates 18. The film 16 and the flat plates 18 may be transferred in the preliminary chamber 12 by the transfer rollers 42. For example, the transfer rollers 42 may consist of 2 or 3 in the preliminary chamber 12. The distance between the transfer rollers 42 may be shorter than the length of the flat plate 18. Additionally, the transfer rollers 42 may horizontally support the flat plates 18 transferred between the flat plate loading chamber 24 and the deposition chamber 34. The transfer rollers 42 may continuously transfer the film 16.

For example, the transfer rollers 42 may include a plurality of parallel rollers 43 and a vertical roller 45 disposed below between the plurality of parallel rollers 43. The plurality of parallel roller 43 and the vertical roller 45 may be disposed in an inverse triangle. The plurality of parallel roller may transfer the film 16 and the flat plates 18 horizontally. The vertical roller 45 may transfer the film 16 being engaged with the horizontal rollers 43.

The film 16 and flat plates 18 may be cleansed by the first plasma 55 induced from the inductive coupled plasma tubes 54. A second heater 64 may be disposed on the film 16 and the flat plates 18 facing the inductive coupled plasma tubes 54. The second heater 64 may optimize a cleansing process by heating the film 16 and the flat plates 18 at about 150° C. Sputter guns 52 may be disposed adjacent to the inductive coupled plasma tubes 54. A buffer layer may be formed on the film 16 and the flat plates 18 through the second plasma 53 induced from the sputter guns 52. At this point, the preliminary chamber 12 may provide a vacuum pressure of a low vacuum state having about 10 mTorr to 100 mTorr using a pumping system. Additionally, an inert gas such as Ar may be supplied to the preliminary chamber 12.

Referring to FIG. 1A through 4B, the deposition chamber 14 may be disposed between the preliminary chamber 12 and the film unloading chamber 24 or the flat unloading chamber 34. The deposition chamber 14 may be constantly connected to the preliminary chamber 12. The deposition chamber 14 may be selectively connected to one of the film unloading chamber 24 and the flat plate unloading chamber 34. The deposition chamber 14 may include a second inlet 15 and a second outlet 17 through which the film 16 or the flat plates 18 enters or exits. The second inlet 15 may be connected to the first outlet 15 of the preliminary chamber 12. The second outlet 17 is selectively connected to one of a first entrance 23 and a second entrance 33 of the film unloading chamber 24.

A plurality of transfer roller 42 may be disposed in the insides at the both sides of the deposition chamber 14. As mentioned above, the transfer roller 42 may horizontally transfer the film 16 and the flat plates 18 in the deposition chamber 14. A plurality of sputter guns 52 and a plurality of inductive coupled plasma tubes 54 may be disposed between the film 16 and the flat plates 18 between the transfer rollers 42. The plurality of inductive coupled plasma tubes 54 may be disposed between one of the film 16 and the flat plates 18 and the plurality of sputter guns 52.

The plurality of sputter guns 52 may sputter deposition particles from the targets 51 by inducing the first plasma 53. The plurality of inductive coupled plasma tubes 54 may induce a more expanded second plasma 55 than the first plasma 53. The second plasma 55 may uniformly mix deposition particles sputtered from the targets 51. The second plasma 20 may increase an ionization rate of an inert gas charged from the first plasma 53. Accordingly, since the thin film depositing apparatus according to the embodiment of the inventive concept may obtain a large quantity of a high-performance thin film, productivity may be increased or maximized.

The deposition chamber 14 may minimize a pollutant that may occur in a high-performance thin film by providing a separate space from the external. The chamber 14 may include a pumping system (not shown) maintaining its inside to be a vacuum pressure of about 0.1 mTorr to about 100 mTorr. Additionally, the chamber 14 may be filled with an inert gas such as Ar, which is a source gas of the first plasma 32 and the second plasma 42.

The plurality of sputter guns 52 may induce the first plasma 53 through a first high frequency power supplied from the external of the chamber 12. The plurality of sputter guns 52 may have a width 36 of about 5 cm to about 20 cm and a length 38 of about 30 cm to about 300 cm. The targets 51 may be disposed on the plurality of sputter guns 52. The targets 34 may include a source material of a thin film formed on the film 16 or the flat plates 18. For example, the targets 51 may include metals such as tungsten, aluminum, titanium, cobalt, nickel, and molybdenum and ceramic such as a silicon oxide layer. The first high frequency power applied to the plurality of sputter guns 30 may charge an inert gas such as Ar into a positive ion of a plasma state through the plurality of sputter guns 52.

The inert gas of a plasma state may be sputtered into the targets 51. A plurality of permanent magnets (not shown) focusing a positive ion of a plasma state may be further disposed on the rear sides of the plurality of sputter guns 52 facing the targets 51. The first plasma 51 sputters deposition particles constituting a thin film formed on the thin film 16 or the flat plates 18 from the targets 51. At this point, the first plasma 53 may be constrained between the plurality of inductive coupled plasma tubes 54.

The plurality of inductive coupled plasma tubes 54 may induce the second plasma 55 through a second high frequency power supplied from the external of the chamber 12. The plurality of inductive coupled plasma tubes 54 may be disposed parallel to the supporters 20. The plurality of inductive coupled plasma tubes 54 may include a rod electrode. Accordingly, the rod electrode may be disposed parallel to the supporters 20 and vertical to a transfer direction of the subject 12 to be processed, which is transferred by the supporters 20. The rod electrode may include a coil to which the second high frequency power is applied and a cover of a glass material surrounding the coil.

The plurality of inductive coupled plasma tubes 54 may be a guard ring of the first plasma 53. The first plasma 53 may be induced between the plurality of inductive coupled plasma tubes 54. Accordingly, the second plasma 55 may be induced in a broader area than the first plasma 53.

Shutters 72 may be disposed between the plurality of inductive coupled plasma tubes 54 and the transfer rollers 42. The shutters 72 may shield the transfer roller 42 from the second plasma 55. The shutters 72 may define a region where the film 16 or the flat plates 18 are exposed through the sputter guns 52 and the inductive coupled plasma tubes 54.

The film 16 or the flat plates 18 may be supported by a supporter roller 44 between the plurality of transfer rollers 42. The supporter roller 44 may be disposed between the plurality of sputter guns 52. Additionally, the supporting roller 44 may be disposed between the plurality of inductive coupled plasma tubes 54. The supporting roller 44 may have a smaller size than the transfer rollers 42. The supporting roller 44 may be protected from the first plasma 53 and the second plasma 55 using a protection cap 74. The protection cap 74 may surround the bottom and side of the supporting roller 44. The protection cap 74 may have a V-shape.

A third heater 66 may be disposed on at least one of the film 16 and the flat plates 18 facing the supporting roller 44. The third heater 66 may apply heat on the film 16 or the flat plates 18 at more than a predetermined temperature. The heater 66 may stabilize the film 16 or the flat plates 18.

As a result, since the thin film depositing apparatus according to the embodiment of the inventive concept may perform a thin film depositing process of the film 16 and the flat plates 18 simultaneously, productivity may be increased or maximized.

As mentioned above, according to embodiments of the present invention, a film loading chamber and a film unloading chamber may be respectively connected through switching to a flat plate loading chamber and a flat plate unlading chamber at the facing both sides of process chambers. The film and flat plates may be moved by rollers in the process chambers. The process chambers may include sputter guns depositing a thin layer on the film and the flat plate and inductive coupled plasma tubes. Accordingly, since the thin film depositing device according to an embodiment of the present invention may be used for both thin film depositing processes of a film and a flat plate during a thin film deposition, productivity may be increased or maximized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film depositing apparatus comprising:
a process chamber including at least one sputter gun inducing a first plasma on a film or a flat plate;
a loading unit provided at one side of the process chamber and including first and second loading chambers loading the film or the flat plate into the process chamber; and
an unloading unit provided at the other side of the process chamber facing the loading unit and first and second unloading chambers unloading the film or the flat plate from the process chamber,
wherein the first loading chamber is connected to the first unloading chamber or the second loading chamber is connected to the second unloading chamber at both sides of the process chamber.

2. The thin film depositing apparatus of claim 1, wherein the process chamber comprises a plurality of rollers transferring and supporting the flat plate or the film.

3. The thin film depositing apparatus of claim 2, wherein the rollers comprise a plurality of transfer rollers are disposed adjacent to the both sidewalls in the process chamber and transferring the flat plate or the film and a supporting roller supporting the flat plate or the film between the plurality of transfer rollers.

4. The thin film depositing apparatus of claim 3, wherein each of the plurality of transfer rollers comprises a plurality of parallel rollers and a vertical roller below between the plurality parallel rollers.

5. The thin film depositing apparatus of claim 4, wherein the process chamber further comprises a protection cap surrounding the supporting roller, being adjacent to the sputter gun.

6. The thin film depositing apparatus of claim 5, wherein the protection cap has a V-shape.

7. The thin film depositing apparatus of claim 3, wherein the process chamber further comprises a plurality of shutters disposed between the sputter gun and the transfer rollers.

8. The thin film depositing apparatus of claim 1, wherein the process chamber comprises a preliminary chamber cleansing the flat plate and the film and a deposition chamber connected to the preliminary chamber and depositing a thin film on the flat plate and the film.

9. The thin film depositing apparatus of claim 8, wherein the deposition chamber further comprises one of the flat plate and the film and a plurality of inductive coupled plasma tubes disposed at both sides between the sputter guns and inducing a more expanded second plasma than the first plasma.

10. The thin film depositing apparatus of claim 1, wherein the first loading chamber further comprises an unwinding roller unwinding the film and the first unloading chamber further comprises a winding roller winding the film.

11. The thin film depositing apparatus of claim 10, wherein each of the first loading chamber and the first unloading chamber further comprises a plurality of film direction changing roller changing a transfer direction of the film and heaters thermally processing the film between the plurality of film direction changing rollers.

12. The thin film depositing apparatus of claim 1, wherein each of the second loading chamber and the second unloading chamber further comprises a cassette elevator loading the flat plate and moving it up and down.
